(19) United States
(12) Patent Application Publication
(10) Pub. No.: US 2025/0183853 A1
(43) Pub. Date: Jun. 5, 2025

(54) DOHERTY AMPLIFIER CIRCUIT

(71) Applicant: Murata Manufacturing Co., Ltd., Kyoto (JP)

(72) Inventors: Shohei IMAI, Kyoto (JP); Fuminori MORISAWA, Kyoto (JP)

(21) Appl. No.: 19/051,006

(22) Filed: Feb. 11, 2025

Related U.S. Application Data
(63) Continuation of application No. PCT/JP2023/029351, filed on Aug. 10, 2023.

(30) Foreign Application Priority Data
Aug. 12, 2022 (JP) 2022-128862

(51) Int. Cl. H03F 1/02; H03F 3/21; H03F 3/213

(52) U.S. Cl. CPC H03F 1/0288; H03F 3/211; H03F 3/213; H03F 2200/24; H03F 2200/451

(57) ABSTRACT

A Doherty amplifier circuit includes a carrier amplifier that amplifies a radio frequency signal; a peak amplifier that amplifies the radio frequency signal; and a control circuit including a first variable bandpass characteristic circuit configured such that a bandpass characteristic for passing the radio frequency signal is variable according to a supply voltage and a detector that detects the radio frequency signal passing through the first variable bandpass characteristic circuit. The control circuit controls the bias of the peak amplifier according to a detection result of the detector.

### CROSS REFERENCE TO RELATED APPLICATION

This is a continuation of International Application No. PCT/JP2023/029351 filed on Aug. 10, 2023 which claims priority from Japanese Patent Application No. 2022-128862 filed on Aug. 12, 2022. The contents of these applications are incorporated herein by reference in their entireties.

### BACKGROUND ART

### Technical Field

The present disclosure relates to a Doherty amplifier circuit.

A Doherty amplifier circuit is known as a high-efficiency power amplifier circuit. Generally, a Doherty amplifier circuit includes a carrier amplifier that operates regardless of the power level of a radio frequency input signal and a peak amplifier that is connected parallel to the carrier amplifier. The peak amplifier is turned off when the power level of the radio frequency input signal is low and turned on when the power level of the radio frequency input signal is high. With this configuration, when the power level of the radio frequency input signal is high, the carrier amplifier operates while maintaining saturation at a saturation output power level. With this configuration, the Doherty amplifier circuit can improve efficiency compared to a normal power amplifier circuit.

In a Doherty amplifier circuit, it is desirable to appropriately control the operation of the peak amplifier to suppress the distortion of a radio frequency output signal and to reduce power consumption.

Non Patent Document 1 below describes an adaptive bias circuit that supplies a bias current to a peak amplifier. When the collector bias voltage decreases, the adaptive bias circuit increases the bias current of the peak amplifier. Also, when the collector bias voltage increases, the adaptive bias circuit decreases the bias current of the peak amplifier.

Non Patent Document 1: Yunsung Cho and four others, “Linear Doherty power amplifier with adaptive bias circuit for average power-tracking”, 2016 IEEE MTT-S International Microwave Symposium (IMS), May 22-27, 2016, pp. 1-3, DOI: 10.1109/MWSYM.2016.7540180

### BRIEF SUMMARY

With the technology described in Non Patent Document 1, there is a problem as described below. For example, when the collector bias voltage has a time delay or a noise error, the activation timing of the peak amplifier is shifted. This may cause the peak amplifier to be activated when it is not necessary and thereby increase the power consumption. Also, this may cause the peak amplifier to be not activated when it is necessary and thereby significantly distort the radio frequency output signal.

The present disclosure suppresses the increase in power consumption and suppress the distortion of a radio frequency output signal.

A Doherty amplifier circuit according to an aspect of the present disclosure includes a carrier amplifier that amplifies a radio frequency signal; a peak amplifier that amplifies the radio frequency signal; and a control circuit including a first variable bandpass characteristic circuit configured such that a bandpass characteristic for passing the radio frequency signal is variable according to a supply voltage and a detector that detects the radio frequency signal passing through the first variable bandpass characteristic circuit. The control circuit controls the bias of the peak amplifier according to a detection result of the detector.

The present disclosure makes it possible to suppress the increase in power consumption and the distortion of a radio frequency output signal.

### BRIEF DESCRIPTION OF THE DRAWINGS

FIG. 1 is a diagram illustrating a configuration of a Doherty amplifier circuit according to a first embodiment.

FIG. 2 is a diagram showing a relationship among a bias voltage, input power, and a supply voltage according to a comparative example.

FIG. 3 is a diagram showing a relationship among a bias voltage, input power, and a supply voltage of a control circuit according to the first embodiment.

FIG. 4 is a diagram illustrating a configuration of a Doherty amplifier circuit according to a second embodiment.

FIG. 5 is a diagram illustrating a configuration of an amplification system according to a third embodiment.

FIG. 6 is a diagram illustrating a configuration of a Doherty amplifier circuit according to a fourth embodiment.

FIG. 7 is a diagram illustrating a configuration of a control circuit according to a fifth embodiment.

FIG. 8 is a diagram showing the bandpass characteristics of a first variable bandpass characteristic circuit of the control circuit of the fifth embodiment.

FIG. 9 is a diagram illustrating a configuration of a control circuit according to a sixth embodiment.

FIG. 10 is a diagram illustrating a configuration of a control circuit according to a seventh embodiment.

FIG. 11 is a diagram illustrating an example of a variable current source circuit.

### DETAILED DESCRIPTION

Embodiments of the present disclosure are described in detail below with reference to the drawings. However, the present disclosure is not limited to the embodiments described below. Needless to say, the embodiments are examples, and partial substitutions and combinations of components in different embodiments may be made. In the second and subsequent embodiments, descriptions of features that are the same as those in the first embodiment are omitted, and only differences are described. In particular, the description of the same effect provided by the same feature is not repeated for each embodiment.

### First Embodiment

### Configuration

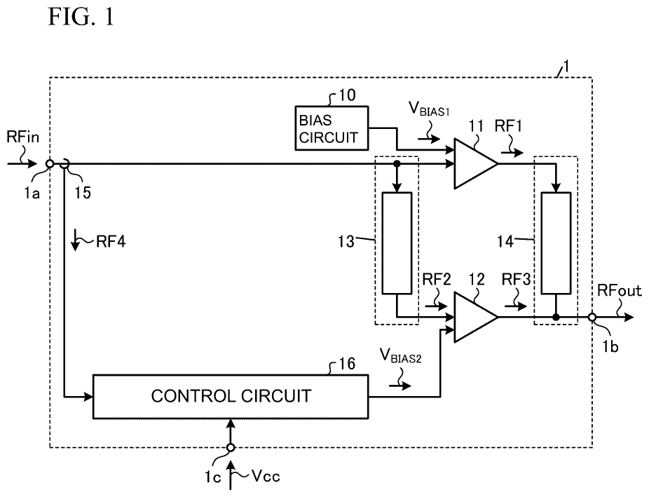

FIG. 1 is a diagram illustrating a configuration of a Doherty amplifier circuit according to a first embodiment. A Doherty amplifier circuit 1 amplifies a radio frequency input signal RFin input to an input terminal la and outputs a radio frequency output signal RFout from an output terminal 1b.

The Doherty amplifier circuit 1 includes a bias circuit 10, a carrier amplifier 11, a peak amplifier 12, a divider 13, a combiner 14, a detector 15, and a control circuit 16.

The bias circuit 10 outputs a bias voltage V_{BIAS1} to the carrier amplifier 11.

The carrier amplifier 11 outputs a radio frequency signal RF1, which is obtained by amplifying the radio frequency input signal RFin, to the combiner 14.

The divider 13 outputs, to the peak amplifier 12, a radio frequency signal RF2 with a phase that is difference from the phase of the radio frequency input signal RFin by approximately 90°. Here, “approximately 90°” indicates not only a phase of 90° but also indicates a phase of 90°±45°. The divider 13 is, for example, a 90° hybrid circuit. However, the present disclosure is not limited to this example.

The peak amplifier 12 outputs a radio frequency signal RF3 obtained by amplifying the radio frequency signal RF2.

The combiner 14 outputs the radio frequency output signal RFout, which is obtained by combining the radio frequency signals RF1 and RF3, from the output terminal 1b of the Doherty amplifier circuit 1.

The detector 15 detects the radio frequency input signal RFin and outputs a radio frequency signal RF4 corresponding to the radio frequency input signal RFin to the control circuit 16.

A supply voltage Vcc, which is supplied to the final stage amplifier, is input to an input terminal 1c of the Doherty amplifier circuit 1. For example, when there is no amplifier after the Doherty amplifier circuit 1, the final stage amplifier corresponds to the carrier amplifier 11 and the peak amplifier 12. As another example, when there is an amplifier after the Doherty amplifier circuit 1, the final stage amplifier corresponds to this amplifier. Here, when there is one or more amplifiers before the Doherty amplifier circuit 1, the supply voltage Vcc supplied to one of the one or more amplifiers may be input to the input terminal 1c of the Doherty amplifier circuit 1. Also, even when there is one or more amplifiers after the Doherty amplifier circuit 1, the supply voltage Vcc supplied to the carrier amplifier 11 and the peak amplifier 12 may be input to the input terminal 1c.

For example, the supply voltage Vcc is a power supply voltage that varies according to the envelope of the radio frequency input signal RFin, that is, an envelope-tracked power supply voltage. However, the present disclosure is not limited to this example.

The control circuit 16 outputs a bias voltage V_{BIAS2} to the peak amplifier 12 based on the radio frequency signal RF4 and the supply voltage Vcc.

### Comparative Example

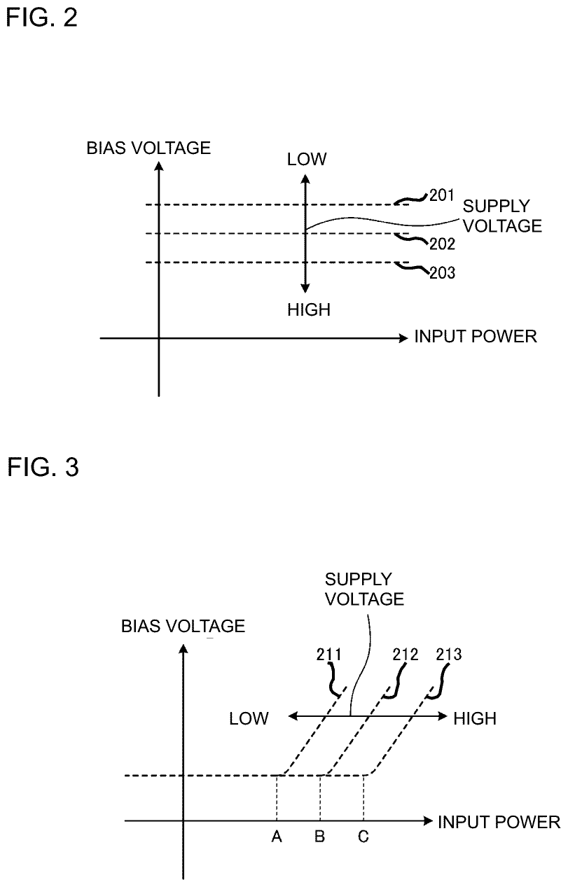

FIG. 2 is a diagram showing a relationship among a bias voltage, input power, and a supply voltage according to a comparative example. In FIG. 2, the vertical axis represents the bias voltage V_{BIAS2}, and the horizontal axis represents the input power of the radio frequency input signal RFin.

In the comparative example, similarly to Non Patent Document 1, the control circuit 16 outputs the bias voltage V_{BIAS2} based only on the supply voltage Vcc without necessarily considering the input power.

A line 201 represents the bias voltage V_{BIAS2} when the supply voltage Vcc is relatively low. A line 202 represents the bias voltage V_{BIAS2} when the supply voltage Vcc is relatively intermediate. A line 203 represents the bias voltage V_{BIAS2} when the supply voltage Vcc is relatively high.

As the supply voltage Vcc decreases, the carrier amplifier 11 becomes more easily saturated. Therefore, in the comparative example, the bias voltage V_{BIAS2} is increased as the supply voltage Vcc decreases so that the peak amplifier 12 is caused to operate (or is activated) more often. On the other hand, as the supply voltage Vcc increases, the carrier amplifier 11 becomes less easily saturated. Therefore, in the comparative example, the bias voltage V_{BIAS2} is decreased as the supply voltage Vcc increases so that the operation of the peak amplifier 12 is suppressed (or stopped).

### Embodiment

FIG. 3 is a diagram showing a relationship among a bias voltage, input power, and a supply voltage of the control circuit according to the first embodiment. In FIG. 3, the vertical axis represents the bias voltage V_{BIAS2}, and the horizontal axis represents the input power of the radio frequency input signal RFin.

The control circuit 16 of the first embodiment outputs the bias voltage V_{BIAS2} based on the input power and the supply voltage Vcc.

A line 211 represents the bias voltage V_{BIAS2} when the supply voltage Vcc is relatively low. A line 212 represents the bias voltage V_{BIAS2} when the supply voltage Vcc is relatively intermediate. A line 213 represents the bias voltage V_{BIAS2} when the supply voltage Vcc is relatively high.

As the supply voltage Vcc decreases, the carrier amplifier 11 becomes more easily saturated. Therefore, the control circuit 16 increases the bias voltage V_{BIAS2} as the supply voltage Vcc decreases so that the peak amplifier 12 is caused to operate (or is activated) more often. On the other hand, as the supply voltage Vcc increases, the carrier amplifier 11 becomes less easily saturated. Therefore, the control circuit 16 decreases the bias voltage V_{BIAS2} as the supply voltage Vcc increases so that the operation of the peak amplifier 12 is suppressed (or stopped).

Also, as the input power increases, the carrier amplifier 11 becomes more easily saturated. Therefore, the control circuit 16 increases the bias voltage V_{BIAS2} as the input power increases so that the peak amplifier 12 is caused to operate (or is activated) more often. On the other hand, as the input power decreases, the carrier amplifier 11 becomes less easily saturated. Therefore, the control circuit 16 decreases the bias voltage V_{BIAS2} as the input power decreases so that the operation of the peak amplifier 12 is suppressed (or stopped).

In summary, a threshold A is set for the input power when the supply voltage Vcc is relatively low (line 211), a threshold B is set for the input power when the supply voltage Vcc is relatively intermediate (line 212), and a threshold C is set for the input power when the supply voltage Vcc is relatively high (line 213). Here, A<B<C. The control circuit 16 maintains the bias voltage V_{BIAS2} constant while the input power is less than the threshold, and increases the bias voltage V_{BIAS2} as the input power increases while the input power is greater than or equal to the threshold.

### Effects

(1) The Doherty amplifier circuit 1 of the first embodiment can reduce the power consumption by suppressing unnecessary operations of the peak amplifier 12 when the supply voltage Vcc suddenly increases.

The supply voltage Vcc is generally determined by the input power. In other words, the supply voltage Vcc increases as the input power increases, and the supply voltage Vcc decreases as the input power decreases. However, due to, for example, the influence of temperature changes and disturbance noise, the supply voltage Vcc may momentarily increase even when the input power is low.

In such a case, in Non Patent Document 1 and the comparative example, it is tried to lower the bias point of the peak amplifier 12. However, due to a lag caused by a delay (time constant) in the control circuit, a state in which the supply voltage Vcc and the bias voltage V_{BIAS2} are high is generated momentarily. As a result, a high supply voltage Vcc is input to the peak amplifier 12, a large bias current flows, and a large amount of power is wasted.

In contrast, in the Doherty amplifier circuit 1, as indicated by the lines 211 to 213 in FIG. 3, when the input power is low, the bias voltage V_{BIAS2} becomes low, and the peak amplifier 12 is stopped. Accordingly, the Doherty amplifier circuit 1 can reduce wasteful power consumption that occurs in Non Patent Document 1 and the comparative example.

(2) The Doherty amplifier circuit 1 of the first embodiment can reduce the activation delay of the peak amplifier 12 when the supply voltage Vcc suddenly drops and can thereby suppress the distortion of the radio frequency output signal RFout.

Contrary to (1) described above, the supply voltage Vcc may momentarily decrease due to the influence of, for example, temperature changes or disturbance noise. This corresponds to, for example, an instantaneous low voltage that occurs when the Doherty amplifier circuit 1 is installed in a vehicle and another device connected to the same power supply system consumes a large current at the start of the engine.

In such a case, in Non Patent Document 1 and the comparative example, it is tried to raise the bias point of the peak amplifier 12. However, due to a lag caused by a delay (time constant) in the control circuit, a state in which the supply voltage Vcc and the bias voltage V_{BIAS2} are low is generated momentarily. As a result, the peak amplifier 12 is not activated, the peak amplifier 12 does not amplify the radio frequency signal RF2, and the radio frequency output signal RFout is greatly distorted.

In contrast, in the Doherty amplifier circuit 1, as indicated by the lines 211 to 213 in FIG. 3, when the input power is high, the bias voltage V_{BIAS2} increases regardless of the supply voltage Vcc, and the peak amplifier 12 is activated. Accordingly, the Doherty amplifier circuit 1 can suppress the distortion of the radio frequency output signal RFout.

### Second Embodiment

The same reference numbers as those in the first embodiment are assigned to components of a second embodiment that are the same as the components of the first embodiment, and descriptions of those components are omitted.

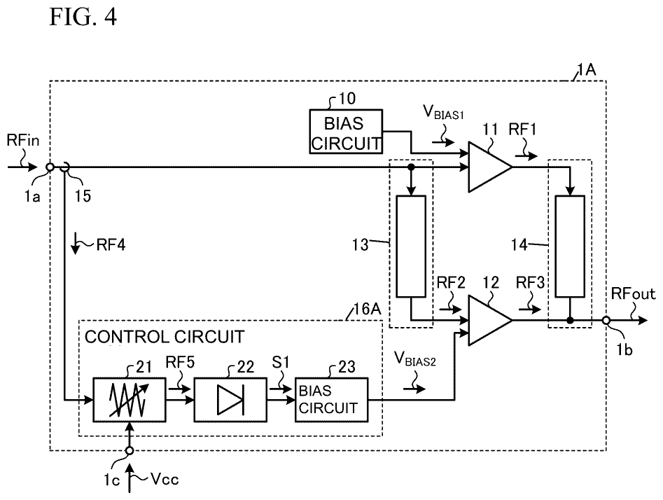

FIG. 4 is a diagram illustrating a configuration of a Doherty amplifier circuit according to a second embodiment.

Different from the Doherty amplifier circuit 1 (see FIG. 1), a Doherty amplifier circuit 1A includes a control circuit 16A instead of the control circuit 16.

The control circuit 16A includes a first variable bandpass characteristic circuit 21, a detector 22, and a bias circuit 23.

In the first variable bandpass characteristic circuit 21, the threshold value of the bandpass characteristic changes and the bandpass characteristic for passing the radio frequency signal RF4 changes according to the supply voltage Vcc. The bandpass characteristic of the first variable bandpass characteristic circuit 21 becomes high when the supply voltage Vcc is relatively low. The bandpass characteristic of the first variable bandpass characteristic circuit 21 becomes low when the supply voltage Vcc is relatively high.

The first variable bandpass characteristic circuit 21 controls the transmission level (transmission degree) of the radio frequency signal RF4 according to the bandpass characteristic and outputs a radio frequency signal RF5 to the detector 22. That is, the power of the radio frequency signal RF5 is determined according to both of the supply voltage Vcc and the input power of the radio frequency input signal RFin.

The detector 22 detects (or rectifies) the radio frequency signal RF5 and outputs a signal S1 corresponding to the radio frequency signal RF5 to the bias circuit 23.

The bias circuit 23 outputs the bias voltage V_{BIAS2} corresponding to the signal S1 to the peak amplifier 12.

Here, the circuit configuration of the detector 22 may be designed to share some of the functions of the bias circuit 23.

### Effects

The control circuit 16A can appropriately control the bias point of the peak amplifier 12 by supplementarily using the supply voltage Vcc. That is, the Doherty amplifier circuit 1A can reduce the power consumption and suppress the distortion of the radio frequency output signal RFout even when the supply voltage Vcc varies due to the influence of, for example, disturbance noise.

### Variation

In the second embodiment, the detector 22 is a single-ended detector. However, the present disclosure is not limited to this example. The detector 22 may be a differential detector. In this case, a balun, which converts the radio frequency signal RF5 to differential radio frequency signals, may be provided between the first variable bandpass characteristic circuit 21 and the detector 22, and the detector 22 may be configured to detect the differential radio frequency signals output from the balun.

### Third Embodiment

The same reference numbers as those in the other embodiments are assigned to components of a third embodiment that are the same as the components of the other embodiments, and descriptions of those components are omitted.

The supply voltage Vcc is often managed by a system controlling the Doherty amplifier circuit 1A. In such a case, the bandpass characteristic of the first variable bandpass characteristic circuit 21 may be digitally controlled according to the supply voltage Vcc being managed by the system. However, controlling the bandpass characteristic of the first variable bandpass characteristic circuit 21 according to the supply voltage Vcc in an analog manner makes it possible to deal with the variation in the supply voltage Vcc, such as the disturbance noise described above, that cannot be managed by the system. In the present disclosure, the bandpass characteristic of the first variable bandpass characteristic circuit 21 may be controlled by an analog process, a digital process, or a combination of analog and digital processes.

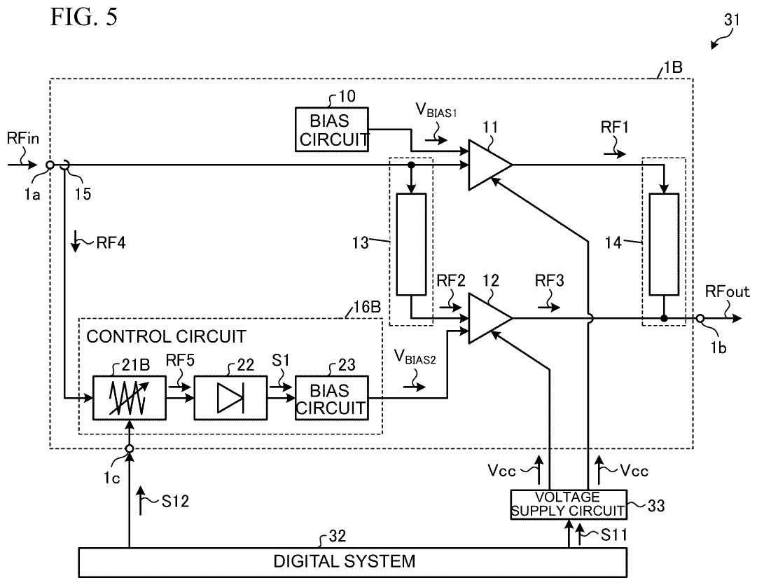

FIG. 5 is a diagram illustrating a configuration of an amplification system according to the third embodiment. An amplification system 31 includes a Doherty amplifier circuit 1B, a digital system 32, and a voltage supply circuit 33.

Different from the Doherty amplifier circuit 1A (see FIG. 4), the Doherty amplifier circuit 1B includes a control circuit 16B instead of the control circuit 16A. Different from the control circuit 16A, the control circuit 16B includes a first variable bandpass characteristic circuit 21B instead of the first variable bandpass characteristic circuit 21.

The digital system 32 controls the entire Doherty amplifier circuit 1B. The digital system 32 is, for example, an envelope tracking circuit. However, the present disclosure is not limited to this example.

The digital system 32 outputs a signal S11 indicating the supply voltage Vcc to the voltage supply circuit 33. For example, when the digital system 32 is an envelope tracking circuit, the digital system 32 varies the signal S11 according to the envelope of the radio frequency input signal RFin. The signal S11 may be a digital signal or an analog signal.

The voltage supply circuit 33 outputs the supply voltage Vcc corresponding to the signal S11 to the carrier amplifier 11 and the peak amplifier 12. The carrier amplifier 11 and the peak amplifier 12 operate using the supply voltage Vcc as a power supply voltage.

The digital system 32 outputs a signal S12 corresponding to the supply voltage Vcc to the first variable bandpass characteristic circuit 21B via the input terminal 1c. For example, when the digital system 32 is an envelope tracking circuit, the digital system 32 varies the signal S12 according to the envelope of the radio frequency input signal RFin. The signal S12 may be a digital signal or an analog signal.

The bandpass characteristic of the first variable bandpass characteristic circuit 21B changes according to the signal S12. That is, the bandpass characteristic of the first variable bandpass characteristic circuit 21B changes according to the supply voltage Vcc. The first variable bandpass characteristic circuit 21B controls the transmission level (transmission degree) of the radio frequency signal RF4 according to the bandpass characteristic and outputs a radio frequency signal RF5 to the detector 22. That is, the power of the radio frequency signal RF5 is determined according to both of the supply voltage Vcc and the input power of the radio frequency input signal RFin.

### Effects

The Doherty amplifier circuit 1B can control the bias voltage V_{BIAS2} of the peak amplifier 12 according to the signal S12 input from the digital system 32. With this configuration, compared to the configuration in which the supply voltage Vcc itself is input (see FIG. 4), the Doherty amplifier circuit 1B can suppress the delay in the control circuit 16B because the signal S12 does not pass through the voltage supply circuit 33.

### Fourth Embodiment

The same reference numbers as those in the other embodiments are assigned to components of a fourth embodiment that are the same as the components of the other embodiments, and descriptions of those components are omitted.

The Doherty amplifier circuit of the present disclosure has a high affinity with other peak amplifier control technologies. For example, the Doherty amplifier circuit of the present disclosure may be used in conjunction with a technology for controlling the activation of a peak amplifier based on the drive level (saturation level) of an amplifier other than the peak amplifier (e.g., a carrier amplifier or an amplifier following the Doherty amplifier circuit 1) and input power.

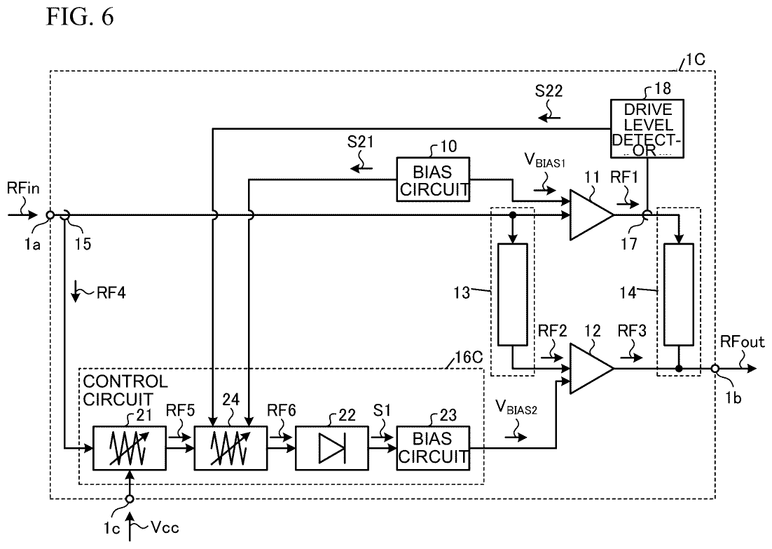

FIG. 6 is a diagram illustrating a configuration of a Doherty amplifier circuit according to the fourth embodiment.

Different from the Doherty amplifier circuit 1A (see FIG. 4), a Doherty amplifier circuit 1C includes a control circuit 16C instead of the control circuit 16A. Different from the control circuit 16A, the control circuit 16C further includes a second variable bandpass characteristic circuit 24.

A signal S21 indicating the drive level of the carrier amplifier 11 is input to the second variable bandpass characteristic circuit 24 from the bias circuit 10. The signal S21 may be a signal (inverted signal) that varies to complement the drive level of the carrier amplifier 11. Also, the Doherty amplifier circuit 1C may include a detector 17 that detects the radio frequency signal RF1 and a drive level detector 18 that outputs a signal S22 indicating the drive level of the carrier amplifier 11 to the second variable bandpass characteristic circuit 24 based on a detection signal of the detector 17. The signal S22 may be a signal (inverted signal) that varies to complement the drive level of the carrier amplifier 11.

At least one of the signal S21 and the signal S22 may be input to the second variable bandpass characteristic circuit 24. Alternatively, a signal obtained by combining the signal S21 and the signal S22 may be input to the second variable bandpass characteristic circuit 24.

In the fourth embodiment, a signal indicating the drive level of the carrier amplifier 11 is input to the control circuit 16C. However, the present disclosure is not limited to this example. A signal indicating the drive level of an amplifier other than the peak amplifier 12 may instead be input to the control circuit 16C. For example, a signal indicating the drive level of an amplifier following the Doherty amplifier circuit 1C may be input to the control circuit 16C.

The bandpass characteristic of the second variable bandpass characteristic circuit 24 changes according to the drive level of the carrier amplifier 11. When the drive level of the carrier amplifier 11 is relatively low, the bandpass characteristic of the second variable bandpass characteristic circuit 24 becomes low. When the drive level of the carrier amplifier 11 is relatively high, the bandpass characteristic of the second variable bandpass characteristic circuit 24 becomes high.

The second variable bandpass characteristic circuit 24 controls the transmission level (transmission degree) of the radio frequency signal RF5 according to the bandpass characteristic and outputs a radio frequency signal RF6 to the detector 22. That is, the power of the radio frequency signal RF6 is determined according to the supply voltage Vcc, the input power of the radio frequency input signal RFin, and the drive level of the carrier amplifier 11.

### Effects

Similarly to the Doherty amplifier circuit 1A, the Doherty amplifier circuit 1C can appropriately control the bias point of the peak amplifier 12 by supplementarily using the supply voltage Vcc. That is, the Doherty amplifier circuit 1C can reduce the power consumption and suppress the distortion of the radio frequency output signal RFout even when the supply voltage Vcc varies due to the influence of, for example, disturbance noise.

Here, the carrier amplifier 11 may be saturated when the temperature or any other surrounding environment changes (for example, when the gain of the carrier amplifier 11 increases at an extremely low temperature), even if the power of the radio frequency input signal RFin is low. To be able to deal with such a case, the second variable bandpass characteristic circuit 24 detects the drive level of the carrier amplifier 11 and immediately activates the peak amplifier 12 when the carrier amplifier 11 is close to saturation, even if the power of the radio frequency signal RF4 is low.

Because the first variable bandpass characteristic circuit 21 detects the radio frequency signal RF4, even if the second variable bandpass characteristic circuit 24 requires time to detect the drive level of the carrier amplifier 11, the control circuit 16C can activate the peak amplifier 12 without necessarily saturating the carrier amplifier 11. With this configuration, the Doherty amplifier circuit 1C can suppress the distortion of the radio frequency output signal RFout.

In other words, the control circuit 16C operates in a feedforward manner according to the radio frequency input signal RFin and operates in a feedback manner according to at least one of the signals S21 and S22.

### Fifth Embodiment

The same reference numbers as those in the other embodiments are assigned to components of a fifth embodiment that are the same as the components of the other embodiments, and descriptions of those components are omitted.

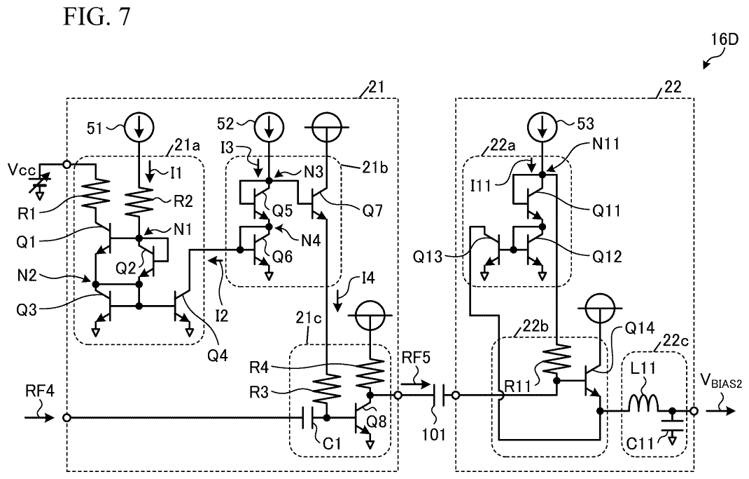

FIG. 7 is a diagram illustrating a configuration of a control circuit according to the fifth embodiment.

A control circuit 16D includes a first variable bandpass characteristic circuit 21 and a detector 22. In the control circuit 16D, because the detector 22 has a high current supply capability, the bias circuit 23 can be omitted. That is, in the control circuit 16D, the detector 22 also includes the function of the bias circuit 23.

The first variable bandpass characteristic circuit 21 includes a drawing unit 21a, a biasing unit 21b, and a signal passing unit 21c.

The drawing unit 21a draws a current I2 from the biasing unit 21b according to the supply voltage Vcc. The drawing unit 21a is a circuit that converts an increase or decrease in the supply voltage Vcc into an increase or decrease in the current I2.

The biasing unit 21b is a circuit that outputs a bias current I4 to the signal passing unit 21c according to the current I2.

The signal passing unit 21c is a circuit that amplifies the radio frequency signal RF4 according to the bias current I4 and outputs the radio frequency signal RF5.

The drawing unit 21a includes resistors R1 and R2 and transistors Q1, Q2, Q3, and Q4.

In the present disclosure, each of the transistors is a bipolar transistor. However, the present disclosure is not limited to this example. An example of the bipolar transistor is a heterojunction bipolar transistor (HBT). However, the present disclosure is not limited to this example. Each of the transistors may instead be, for example, a field-effect transistor (FET). Each of the transistors may also be a multi-finger transistor that is implemented by electrically connecting multiple unit transistors in parallel with each other. A unit transistor refers to a transistor with the minimum configuration.

When each of the transistors is an FET, the drain of the FET corresponds to the collector of the bipolar transistor, the gate of the FET corresponds to the base of the bipolar transistor, and the source of the FET corresponds to the emitter of the bipolar transistor.

The supply voltage Vcc is input to a first end of the resistor R1. A second end of the resistor R1 is electrically connected to the collector of the transistor Q1.

The base of the transistor Q1 is electrically connected to a node N1. The emitter of the transistor Q1 is electrically connected to a node N2.

A set constant current I1 is input from a current source 51 to a first end of the resistor R2. A second end of the resistor R2 is electrically connected to the node N1.

The collector and the base of the transistor Q2 are electrically connected to the node N1. That is, the transistor Q1 and the transistor Q2 are connected in a current mirror configuration. The emitter of the transistor Q2 is electrically connected to the node N2.

The collector and the base of the transistor Q3 are electrically connected to the node N2. The emitter of the transistor Q3 is electrically connected to a reference potential.

The base of the transistor Q4 is electrically connected to the node N2. In other words, the transistor Q3 and the transistor Q4 are connected in a current mirror configuration. The emitter of the transistor Q4 is electrically connected to the reference potential. The collector of the transistor Q4 is electrically connected to a node N4 of the biasing unit 21b.

The current I2 flowing from the node N4 to the collector of the transistor Q4 is the output current of the drawing unit 21a.

The biasing unit 21b includes transistors Q5, Q6, and Q7.

The collector and the base of the transistor Q5 are electrically connected to a node N3. That is, the transistor Q5 is diode-connected. A set constant current I3 is input from a current source 52 to the node N3. The emitter of the transistor Q5 is electrically connected to the node N4.

The collector and the base of the transistor Q6 are electrically connected to the node N4. That is, the transistor Q6 is diode-connected. The emitter of the transistor Q6 is electrically connected to the reference potential.

A power supply voltage is input to the collector of the transistor Q7. The base of the transistor Q7 is electrically connected to the node N3. That is, the transistor Q5 and the transistor Q7 are connected in a current mirror configuration. The emitter of the transistor Q7 is electrically connected to a first end of a resistor R3 of the signal passing unit 21c. That is, the transistor Q7 and the resistor R3 are connected in an emitter-follower configuration.

The emitter current of the transistor Q7 corresponds to the bias current I4.

The signal passing unit 21c includes resistors R3 and R4, a capacitor C1, and a transistor Q8.

A second end of the resistor R3 is electrically connected to the base of the transistor Q8. The bias current I4 flowing into the first end of the resistor R3 is input to the base of the transistor Q8.

The radio frequency signal RF4 is input to a first end of the capacitor C1. A second end of the capacitor C1 is electrically connected to the base of the transistor Q8. The capacitor C1 is a DC blocking capacitor that blocks the direct current component of the radio frequency signal RF4.

A power supply voltage is input to a first end of the resistor R4. A second end of the resistor R4 is electrically connected to the collector of the transistor Q8.

The emitter of the transistor Q8 is electrically connected to the reference potential.

The signal passing unit 21c amplifies the radio frequency signal RF4 according to the bias current I4 and outputs the radio frequency signal RF5 from the collector.

Operations of the first variable bandpass characteristic circuit 21 are described below.

The voltage of the node N1 of the drawing unit 21a is approximately 2V_{BE} when the base-emitter voltage of each transistor is V_{BE}.

A case where the supply voltage Vcc is relatively low (lower than 2V_{BE}) is described.

In this case, the constant current I1 flows toward the supply voltage Vcc via the PN junction between the base and the collector of the transistor Q1. Therefore, no current flows into the node N2. Accordingly, the current I2 does not flow between the collector and the emitter of the transistor Q4.

Because the current I2 does not flow, approximately the entire constant current I3 flows to the diode-connected transistor Q5 and the diode-connected transistor Q6. As a result, a relatively high bias voltage is applied to the base of the transistor Q7, and the emitter current of the transistor Q7 becomes relatively high. That is, the biasing unit 21b outputs a relatively large bias current I4 to the base of the transistor Q8 of the signal passing unit 21c.

When the relatively large bias current I4 is input to the base, the transistor Q8 outputs the radio frequency signal RF5 with relatively high power.

In summary, the first variable bandpass characteristic circuit 21 relatively increases the power of the radio frequency signal RF5 when the supply voltage Vcc is relatively low.

Next, a case where the supply voltage Vcc increases is described.

As the supply voltage Vcc increases, the transistor Q1 gradually starts to operate properly, and the transistor Q1 and the transistor Q2 start to operate as a current mirror.

The constant current I1 flows into the node N2 via the collector (base) and the emitter of the transistor Q2. Also, when the transistors Q1 and Q2 operate as a current mirror, the emitter current of the transistor Q1, which is proportional to the emitter current of the transistor Q2, flows into the node N2. The current flowing into the node N2 flows between the collector (base) and the emitter of the transistor Q3.

The transistors Q3 and 04 are connected in a current mirror configuration. Therefore, the current I2 proportional to the current flowing into the node N2 flows between the collector and the emitter of the transistor Q4.

Because the current I2 flows out from the node N4 to the collector of the transistor Q4, a current obtained by subtracting the current I2 from the constant current I3 flows into the transistor Q6. As a result, the collector-emitter voltage of the transistor Q6 becomes relatively low, a relatively low bias voltage is applied to the base of the transistor Q7, and therefore the emitter current of the transistor Q7 becomes relatively small. That is, the biasing unit 21b outputs a relatively small bias current I4 to the base of the transistor Q8 of the signal passing unit 21c.

When a relatively small bias current I4 is input to the base, the transistor Q8 outputs the radio frequency signal RF5 with a relatively low power.

The radio frequency signal RF5 output from the first variable bandpass characteristic circuit 21 is input to the detector 22 via the DC blocking capacitor 101.

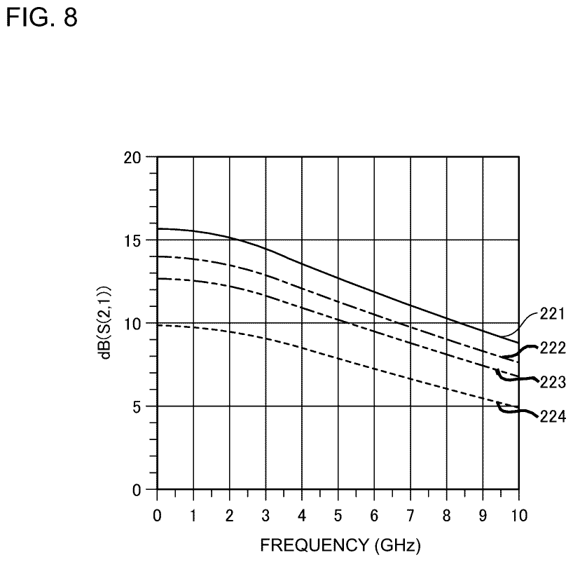

FIG. 8 is a diagram showing the bandpass characteristics of the first variable bandpass characteristic circuit of the control circuit of the fifth embodiment. In FIG. 8, the vertical axis represents a scattering(S) parameter (S(2,1)) of the first variable bandpass characteristic circuit 21, and the horizontal axis represents a frequency.

The threshold of the bandpass characteristic of the first variable bandpass characteristic circuit 21 changes according to the supply voltage. A line 221 indicates the S parameter of the first variable bandpass characteristic circuit 21 when the supply voltage Vcc is 2.0 V. A line 222 indicates the S parameter of the first variable bandpass characteristic circuit 21 when the supply voltage Vcc is 3.0 V. A line 223 indicates the S parameter of the first variable bandpass characteristic circuit 21 when the supply voltage Vcc is 4.0 V. A line 224 indicates the S parameter of the first variable bandpass characteristic circuit 21 when the supply voltage Vcc is 5.0 V.

As shown in FIG. 8, in the range from 0 GHz to 10 GHz, the S parameter of the first variable bandpass characteristic circuit 21 increases as the supply voltage Vcc decreases, and the S parameter of the first variable bandpass characteristic circuit 21 decreases as the supply voltage Vcc increases.

Referring back to FIG. 7, the detector 22 includes a biasing unit 22a, a detection unit 22b, and a filter unit 22c.

The biasing unit 22a includes transistors Q11, Q12, and Q13.

The collector and the base of the transistor Q11 are electrically connected to a node N11. That is, the transistor Q11 is diode-connected. A set constant current I11 is input from a current source 53 to the node N11.

The collector and the base of the transistor Q12 are electrically connected to the emitter of the transistor Q11. That is, the transistor Q12 is diode-connected. The emitter of the transistor Q12 is electrically connected to the reference potential.

Accordingly, the voltage at the node N11 becomes approximately 2V_{BE}.

The base of the transistor Q13 is electrically connected to the collector and the base of the transistor Q12. That is, the transistor Q12 and the transistor Q13 are connected in a current mirror configuration. The emitter of the transistor Q13 is electrically connected to the reference potential.

The detection unit 22b includes a resistor R11 and a transistor Q14.

A first end of the resistor R11 is electrically connected to the node N11. A second end of the resistor R11 is electrically connected to the base of the transistor Q14.

That is, the base bias voltage of the transistor Q14 is determined by the voltage at the node N11.

The power supply voltage is input to the collector of the transistor Q14. The radio frequency signal RF5, which has passed through the DC blocking capacitor 101, is input to the base of the transistor Q14. The emitter of the transistor Q14 is electrically connected to the collector of the transistor Q13.

A certain portion of the emitter current of the transistor Q14 flows between the collector and the emitter of the transistor Q13, and the remaining portion of the emitter current flows to the filter unit 22c.

The filter unit 22c includes an inductor L11 and a capacitor C11. The filter unit 22c is a low pass filter that removes the fundamental wave component of the radio frequency signal RF5. The filter unit 22c may be omitted when the detector 22 is a differential detector.

A first end of the inductor L11 is electrically connected to the emitter of the transistor Q14. A second end of the inductor L11 is electrically connected to a first end of the capacitor C11. A second end of the capacitor C11 is electrically connected to the reference potential. The voltage of the capacitor C11 becomes the bias voltage V_{BIAS2} of the peak amplifier 12.

Operations of the detector 22 are described below.

The transistor Q14 is turned on when the radio frequency signal RF5 is greater than or equal to the threshold voltage of the transistor Q14 and outputs the emitter current.

That is, as the amplitude of the radio frequency signal RF5 increases, the emitter current of the transistor Q14 increases. Also, as the amplitude of the radio frequency signal RF5 decreases, the emitter current of the transistor Q14 decreases.

A certain portion of the emitter current of the transistor Q14 flows between the collector and the emitter of the transistor Q13, and the remaining portion of the emitter current flows to the filter unit 22c.

Accordingly, as the amplitude of the radio frequency signal RF5 increases, the bias voltage V_{BIAS2} increases. Also, as the amplitude of the radio frequency signal RF5 decreases, the bias voltage V_{BIAS2} decreases.

### Effects

The control circuit 16D can implement a circuit that appropriately controls the bias point of the peak amplifier 12 by supplementarily using the supply voltage Vcc. That is, the control circuit 16C can implement a circuit that can reduce the power consumption and suppress the distortion of the radio frequency output signal RFout even when the supply voltage Vcc varies due to the influence of, for example, disturbance noise.

### Sixth Embodiment

The same reference numbers as those in the other embodiments are assigned to components of a sixth embodiment that are the same as the components of the other embodiments, and descriptions of those components are omitted.

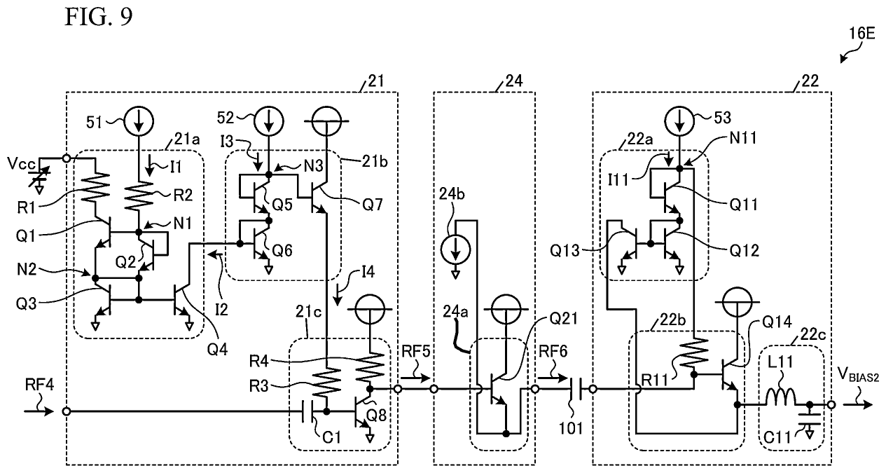

FIG. 9 is a diagram illustrating a configuration of a control circuit according to the sixth embodiment.

Compared to the control circuit 16D (see FIG. 7), a control circuit 16E further includes the second variable bandpass characteristic circuit 24.

The second variable bandpass characteristic circuit 24 includes a signal passing unit 24a and a current source 24b.

The signal passing unit 24a includes a transistor Q21.

The power supply voltage is input to the collector of the transistor Q21. The radio frequency signal RF5 is input to the base of the transistor Q21. The emitter of the transistor Q21 is electrically connected to the current source 24b.

The current source 24b draws, from the emitter of the transistor Q21, an electric current corresponding to at least one of the signal S21 and the signal S22 indicating the drive level of the carrier amplifier 11.

The current source 24b draws a large current from the emitter of the transistor Q21 when the carrier amplifier 11 is saturated. As a result, the transistor Q21 operates as an emitter-follower circuit and maintains the bandpass characteristic at a high level.

On the other hand, the current source 24b does not provide an appropriate bias to the emitter of the transistor Q21 when the carrier amplifier 11 is not saturated. As a result, the bandpass characteristic of the transistor Q21 becomes low.

### Effects

The carrier amplifier 11 may be saturated when the temperature or any other surrounding environment changes (for example, when the gain of the carrier amplifier 11 increases at an extremely low temperature), even if the power of the radio frequency input signal RFin is low. The control circuit 16E can implement a circuit that, to be able to deal with such a situation, detects the drive level of the carrier amplifier 11 and immediately activates the peak amplifier 12 when the carrier amplifier 11 is close to saturation, even if the power of the radio frequency signal RF4 is low.

### Seventh Embodiment

The same reference numbers as those in the other embodiments are assigned to components of a seventh embodiment that are the same as the components of the other embodiments, and descriptions of those components are omitted.

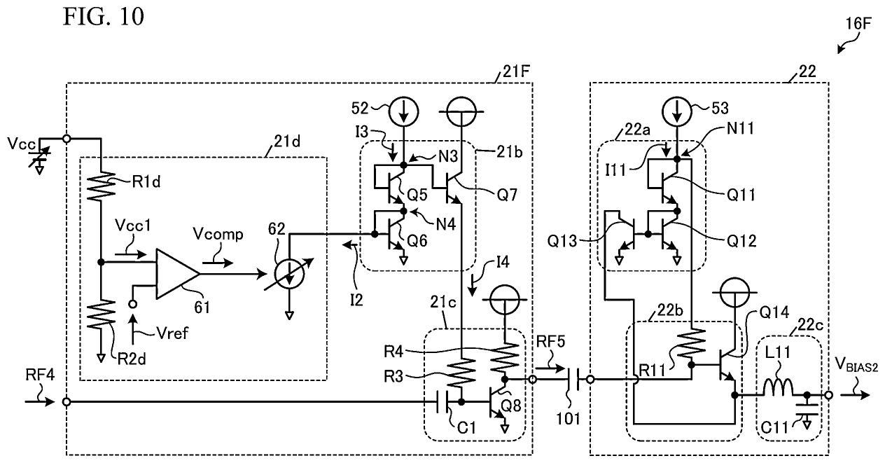

FIG. 10 is a diagram illustrating a configuration of a control circuit according to the seventh embodiment.

A control circuit 16F is different from the control circuit 16D (see FIG. 7) in a part of the configuration of the first variable bandpass characteristic circuit 21. Specifically, in the control circuit 16F, different from the first variable bandpass characteristic circuit 21, a first variable bandpass characteristic circuit 21F includes a drawing unit 21d instead of the current source 51 and the drawing unit 21a.

The drawing unit 21d includes resistors R1d and R2d, a comparator 61, and a variable current source circuit 62.

The supply voltage Vcc is input to a first end of the resistor R1d. A second end of the resistor R1d is electrically connected to a first end of the resistor R2d. A second end of the resistor R2d is electrically connected to the reference potential.

The comparator 61 includes a first input terminal, a second input terminal, and an output terminal. The connection point between the second end of the resistor Rd and the first end of the resistor R2d is electrically connected to the first input terminal of the comparator 61, and a voltage Vcc1, which is obtained by dividing the supply voltage Vcc by the resistor R1d and the resistor R2d, is applied to the first input terminal. A reference voltage Vref is applied to the second input terminal of the comparator 61. The comparator 61 compares the voltage Vcc1 applied to the first input terminal with the reference voltage Vref applied to the second input terminal and outputs a comparison result output signal Vcomp indicating the comparison result from the output terminal.

The variable current source circuit 62 is electrically connected to the output terminal of the comparator 61. The variable current source circuit 62 draws the current I2 from the biasing unit 21b according to the comparison result output signal Vcomp output from the output terminal of the comparator 61. In other words, the variable current source circuit 62 converts an increase or decrease in the supply voltage Vcc into an increase or decrease in the current I2 and draws the current I2 from the biasing unit 21b according to the supply voltage Vcc.

Operations of the drawing unit 21D and operations of the first variable bandpass characteristic circuit 21F are described below.

A case where the supply voltage Vcc is relatively low (lower than the reference voltage Vref) is described.

In this case, the comparator 61 outputs a low-level signal as the comparison result output signal Vcomp. When the low-level comparison result output signal Vcomp is input, the variable current source circuit 62 is not driven and is turned off. Therefore, the current I2 does not flow.

Because the current I2 does not flow, approximately the entire constant current I3 flows to the transistor Q5 and the transistor Q6 included in the biasing unit 21b. As a result, a relatively high bias voltage is applied to the base of the transistor Q7, and the emitter current of the transistor Q7 becomes relatively large. That is, the biasing unit 21b outputs a relatively large bias current I4 to the base of the transistor Q8 of the signal passing unit 21c.

When the relatively large bias current I4 is input to the base, the transistor Q8 outputs the radio frequency signal RF5 with relatively high power.

In summary, the first variable bandpass characteristic circuit 21F relatively increases the power of the radio frequency signal RF5 when the supply voltage Vcc is relatively low.

Next, a case where the supply voltage Vcc increases to a relatively high level (which is higher than the reference voltage Vref) is described.

In this case, the comparator 61 outputs a high-level signal as the comparison result output signal Vcomp. When the high-level comparison result output signal Vcomp is input, the variable current source circuit 62 is driven and turned on. As a result, the current I2 proportional to the magnitude of the comparison result output signal Vcomp starts to flow.

Because the current I2 flows out to the variable current source circuit 62, a current obtained by subtracting the current I2 from the constant current I3 flows to the transistor Q6 of the biasing unit 21b. As a result, the collector-emitter voltage of the transistor Q6 becomes relatively low, a relatively low bias voltage is applied to the base of the transistor Q7, and therefore the emitter current of the transistor Q7 becomes relatively small. That is, the biasing unit 21b outputs a relatively small bias current I4 to the base of the transistor Q8 of the signal passing unit 21c.

When the relatively small bias current I4 is input to the base, the transistor Q8 outputs the radio frequency signal RF5 with a relatively low power.

In summary, when the supply voltage Vcc increases to a relatively high level, the first variable bandpass characteristic circuit 21F increases the power of the radio frequency signal RF5 to a relatively high level.

The control circuit 16F may include multiple semiconductor dies. Specifically, for example, the drawing unit 21d and the current source 52 included in the first variable bandpass characteristic circuit 21F of the control circuit 16F may be formed on a first semiconductor die including a semiconductor substrate formed of silicon (Si). Also, for example, remaining components of the control circuit 16F excluding the drawing unit 21d and the current source 52 may be formed on a second semiconductor die including a semiconductor substrate formed of gallium arsenide (GaAs). In addition to the drawing unit 21d and the current source 52 of the control circuit 16F, other control circuits for controlling the carrier amplifier 11 and the peak amplifier 12 may be formed on the first semiconductor die. Also, in addition to the remaining components of the control circuit 16F, the carrier amplifier 11 and the peak amplifier 12 may be formed on the second semiconductor die.

An example of the variable current source circuit 62 is described below.

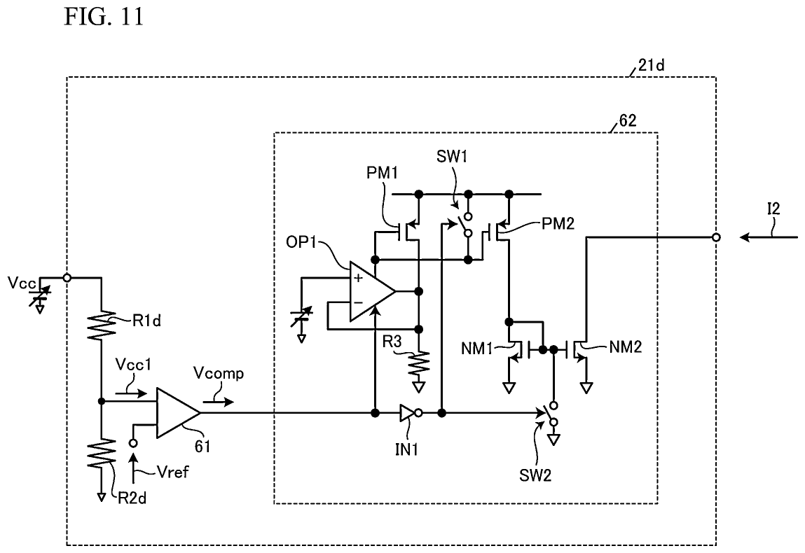

FIG. 11 is a diagram illustrating an example of the variable current source circuit 62.

For example, the variable current source circuit 62 includes an operational amplifier OP1, an inverter IN1, PMOS transistors PM1 and PM2, switches SW1 and SW2, NMOS transistors NM1 and NM2, and a resistor R3.

The operational amplifier OP1 includes a non-inverting input terminal, an inverting input terminal, and an output terminal. The non-inverting input terminal of the operational amplifier OP1 is connected to the reference potential. The inverting input terminal of the operational amplifier OP1 is connected to a first end of the resistor R3 and the output terminal of the operational amplifier OP1. A second end of the resistor R3 is grounded.

The source terminal of the PMOS transistor PM1 is connected to a fixed potential (for example, a power supply potential). The drain terminal of the PMOS transistor PM1 is connected to the output terminal of the operational amplifier OP1. The gate of the PMOS transistor PM1 is connected to the gate of the PMOS transistor PM2 and a first end of the switch SW1.

The source terminal of the PMOS transistor PM2 is connected to a fixed potential (for example, a power supply potential). The drain terminal of the PMOS transistor PM2 is connected to the drain of the NMOS transistor NM1. The gate of the PMOS transistor PM2 is connected to the gate of the PMOS transistor PM1 and the first end of the switch SW1.

The first end of the switch SW1 is connected to the gates of the PMOS transistors PM1 and PM2, and the second end of the switch SW1 is connected to a fixed potential (e.g., the power supply potential).

In the NMOS transistor NM1, the drain is connected to the gate, and the source is grounded. In the NMOS transistor NM2, the drain is connected to the biasing unit 21b, the gate is connected to the gate of the NMOS transistor NM1, and the source is grounded. That is, the NMOS transistors NM1 and NM2 constitute a current mirror circuit. The gate of the NMOS transistor NM1 and the gate of the NMOS transistor NM2 are grounded via the switch SW2.

The comparison result output signal Vcomp output from the output terminal of the comparator 61 is input to the operational amplifier OP1 as a control signal. Also, the comparison result output signal Vcomp output from the output terminal of the comparator 61 is input to each of the switches SW1 and SW2 as a control signal via the inverter IN1.

When the comparator 61 outputs a low-level signal as the comparison result output signal Vcomp, the operational amplifier OP1, to which the low-level signal is input as a control signal, is turned off. Also, each of the switches SW1 and SW2, to which a high-level signal obtained by inverting the low-level signal is input as a control signal, is closed. In this case, because of the switch SW1, the gate potential and the source potential of each of the PMOS transistors PM1 and PM2 become the same. Also, because of the switch SW2, the gate of the NMOS transistor NM1 and the gate of the NMOS transistor NM2 are fixed to the ground potential. Therefore, the variable current source circuit 62 is turned off.

When the comparator 61 outputs a high-level signal as the comparison result output signal Vcomp, the operational amplifier OP1, to which the high-level signal is input as a control signal, is turned on. Also, each of the switches SW1 and SW2, to which a low-level signal obtained by inverting the high-level signal is input as a control signal, is opened. In this case, because of the switch SW1, the gate potential and the source potential of each of the PMOS transistors PM1 and PM2 become different from each other. Also, because of the switch SW2, the gate of the NMOS transistor NM1 and the gate of the NMOS transistor NM2 are not fixed to the ground potential. Therefore, the variable current source circuit 62 is turned on.

### Examples of Configurations of Present Disclosure

The present disclosure may be implemented through configurations described below.

(1)

A Doherty amplifier circuit includes a carrier amplifier that amplifies a radio frequency signal; a peak amplifier that amplifies the radio frequency signal; and a control circuit including a first variable bandpass characteristic circuit configured such that a bandpass characteristic for passing the radio frequency signal is variable according to a supply voltage and a detector that detects the radio frequency signal passing through the first variable bandpass characteristic circuit. The control circuit controls the bias of the peak amplifier according to a detection result of the detector.

(2)

The Doherty amplifier circuit as described in (1). The control circuit further includes a second variable bandpass characteristic circuit that is electrically connected between the first variable bandpass characteristic circuit and the detector and configured such that a bandpass characteristic for passing the radio frequency signal is variable according to a drive level of an amplifier other than the peak amplifier.

(3)

The Doherty amplifier circuit as described in (1) or (2). The first variable bandpass characteristic circuit includes a passing unit that passes the radio frequency signal, a biasing unit that controls the bias of the passing unit, and a drawing unit that draws an electric current from the biasing unit according to the supply voltage.

(4)

The Doherty amplifier circuit as described in (3). The drawing unit includes a first transistor configured such that the supply voltage is input to a collector or a drain, a base or a gate is electrically connected to a first node into which a constant current flows, and an emitter or a source is electrically connected to a second node, a second transistor configured such that a collector or a drain and a base or a gate are electrically connected to the first node and an emitter or a source is electrically connected to the second node, a third transistor configured such that a collector or a drain and a base or a gate are electrically connected to the second node and an emitter or a source is electrically connected to a reference potential, and a fourth transistor configured such that a base or a gate is electrically connected to the second node and an emitter or a source is electrically connected to the reference potential. The fourth transistor draws an electric current from the biasing unit to a collector.

(5)

The Doherty amplifier circuit as described in any one of (1) to (4). The supply voltage is a power supply voltage supplied to a final stage amplifier or a voltage corresponding to the power supply voltage.

(6)

A Doherty amplifier circuit includes a carrier amplifier that amplifies a radio frequency signal; a peak amplifier that amplifies the radio frequency signal; and a control circuit that controls the bias of the peak amplifier. The control circuit includes a first variable bandpass characteristic circuit configured such that a first bandpass characteristic for passing the radio frequency signal is variable, a threshold of a bandpass characteristic varies according to a supply voltage, and the first bandpass characteristic decreases as the supply voltage increases, and a detector that detects the radio frequency signal that has passed through the first variable bandpass characteristic circuit. The control circuit controls the bias of the peak amplifier according to a detection result of the detector.

(7)

The Doherty amplifier circuit as described in (1) or (6). The control circuit further includes a second variable bandpass characteristic circuit that is electrically connected between the first variable bandpass characteristic circuit and the detector and configured such that a second bandpass characteristic for passing the radio frequency signal is variable and the second bandpass characteristic increases as the drive level of an amplifier other than the peak amplifier increases.

(8)

A Doherty amplifier circuit includes a carrier amplifier that amplifies a radio frequency signal; a peak amplifier that amplifies the radio frequency signal; and a control circuit that controls the bias of the peak amplifier. The control circuit controls the bias of the peak amplifier according to a supply voltage and the radio frequency signal.

(9)

The Doherty amplifier circuit as described in (8). The control circuit controls the bias of the peak amplifier also according to a drive level of an amplifier other than the peak amplifier.

(10)

The Doherty amplifier circuit as described in (8) or (9). The control circuit includes a first variable bandpass characteristic circuit configured such that a bandpass characteristic for passing the radio frequency signal is variable according to a supply voltage, and a detector that detects the radio frequency signal passing through the first variable bandpass characteristic circuit.

(11)

The Doherty amplifier circuit as described in (3). The drawing unit includes a first resistor element having a first end to which the supply voltage is input, a second resistor element having a first end electrically connected to a second end of the first resistor element and a second end electrically connected to a reference potential, a comparator that includes a first input terminal, a second input terminal, and an output terminal and is configured such that a signal output from a connection point between the second end of the first resistor element and the first end of the second resistor element is input to the first input terminal, a reference voltage is input to the second input terminal, and a comparison result output signal is output from the output terminal, and a variable current source circuit that changes the electric current drawn from the biasing unit according to the comparison result output signal output from the output terminal of the comparator.

(12)

The Doherty amplifier circuit as described in (11). The drawing unit of the first variable bandpass characteristic circuit is formed on a first semiconductor die, the passing unit and the biasing unit of the first variable bandpass characteristic circuit are formed on a second semiconductor die, and the material of a first semiconductor substrate included in the first semiconductor die is different from the material of a second semiconductor substrate included in the second semiconductor die.

The above-described embodiments are intended to facilitate the understanding of the present disclosure and are not intended to limit the scope of the present disclosure. The present disclosure may be modified or improved without necessarily departing from the spirit of the present disclosure, and the present disclosure may include its equivalents.

### Reference Signs List

1, 1A, 1B, 1C Doherty amplifier circuit
10, 23 bias circuit
11 carrier amplifier
12 peak amplifier
13 Divider
14 combiner
15 detector
16, 16A, 16B, 16C, 16D, 16E, 16F control circuit
21, 21B, 21F first variable bandpass characteristic circuit
21a, 21d drawing unit
21b, 22a biasing unit
21c signal passing unit
22 detector
22b detection unit
22c filter unit
24 second variable bandpass characteristic circuit
24a signal passing unit
24b current source
31 amplification system
32 digital system
33 voltage supply circuit
61 comparator
62 variable current source circuit

1. A Doherty amplifier circuit comprising:
a carrier amplifier configured to amplify a radio frequency signal;
a peak amplifier configured to amplify the radio frequency signal; and
a control circuit comprising:
a first variable bandpass circuit configured such that a bandpass for passing the radio frequency signal is variable according to a supply voltage, and
a detector configured to detect the radio frequency signal passing through the first variable bandpass circuit,
wherein the control circuit is configured to control a bias of the peak amplifier according to a detection result of the detector.

2. The Doherty amplifier circuit according to claim 1, wherein the control circuit comprises a second variable bandpass circuit that is electrically connected between the first variable bandpass circuit and the detector, and configured such that a bandpass for passing the radio frequency signal is variable according to a drive level of an amplifier other than the peak amplifier.

3. The Doherty amplifier circuit according to claim 1, wherein the first variable bandpass circuit comprises:
a passing circuit configured to pass the radio frequency signal,
a biasing circuit configured to control a bias of the passing circuit, and
a drawing circuit that draws an electric current from the biasing circuit according to the supply voltage.

4. The Doherty amplifier circuit according to claim 3, wherein the drawing circuit comprises:
a first transistor configured such that the supply voltage is input to a collector or a drain, a base or a gate is electrically connected to a first node into which a constant current flows, and an emitter or a source is electrically connected to a second node,
a second transistor configured such that a collector or a drain and a base or a gate are electrically connected to the first node and an emitter or a source is electrically connected to the second node,
a third transistor configured such that a collector or a drain and a base or a gate are electrically connected to the second node and an emitter or a source is electrically connected to a reference potential, and
a fourth transistor configured such that a base or a gate is electrically connected to the second node and an emitter or a source is electrically connected to the reference potential,
wherein the fourth transistor is configured to draw an electric current from the biasing circuit to a collector or a drain.

5. The Doherty amplifier circuit according to claim 1, wherein the supply voltage is a power supply voltage supplied to a final stage amplifier or a voltage corresponding to the power supply voltage.

6. A Doherty amplifier circuit comprising:
a carrier amplifier configured to amplify a radio frequency signal;
a peak amplifier configured to amplify the radio frequency signal; and
a control circuit configured to control a bias of the peak amplifier,
wherein the control circuit comprises:
a first variable bandpass circuit configured such that a first bandpass for passing the radio frequency signal is variable, a threshold of a bandpass varies according to a supply voltage, and the first bandpass decreases as the supply voltage increases, and
a detector configured to detect the radio frequency signal that has passed through the first variable bandpass circuit; and
the control circuit is configured to control the bias of the peak amplifier according to a detection result of the detector.

7. The Doherty amplifier circuit according to claim 1, wherein the control circuit comprises a second variable bandpass circuit that is electrically connected between the first variable bandpass circuit and the detector, and configured such that a second bandpass for passing the radio frequency signal is variable and the second bandpass increases as a drive level of an amplifier other than the peak amplifier increases.

8. A Doherty amplifier circuit comprising:
a carrier amplifier configured to amplify a radio frequency signal;
a peak amplifier configured to amplify the radio frequency signal; and
a control circuit configured to control a bias of the peak amplifier,
wherein the control circuit is configured to control the bias of the peak amplifier according to a supply voltage and the radio frequency signal.

9. The Doherty amplifier circuit according to claim 8, wherein the control circuit is configured to control the bias of the peak amplifier according to a drive level of an amplifier other than the peak amplifier.

10. The Doherty amplifier circuit according to claim 8, wherein the control circuit comprises:
a first variable bandpass circuit configured such that a bandpass for passing the radio frequency signal is variable according to a supply voltage, and
a detector configured to detect the radio frequency signal passing through the first variable bandpass characteristic circuit.

11. The Doherty amplifier circuit according to claim 3, wherein the drawing circuit comprises:
a first resistor element having a first end to which the supply voltage is input,
a second resistor element having a first end electrically connected to a second end of the first resistor element and a second end electrically connected to a reference potential,
a comparator comprising a first input terminal, a second input terminal, and an output terminal, and configured such that a signal output from a connection point between the second end of the first resistor element and the first end of the second resistor element is input to the first input terminal, a reference voltage is input to the second input terminal, and a comparison result output signal is output from the output terminal, and
a variable current source circuit configured to change the electric current drawn from the biasing circuit according to the comparison result output signal output from the output terminal of the comparator.

12. The Doherty amplifier circuit according to claim 11, wherein the drawing circuit of the first variable bandpass circuit is formed on a first semiconductor die;
wherein the passing circuit and the biasing circuit of the first variable bandpass circuit are formed on a second semiconductor die;
wherein the first semiconductor die comprises a first semiconductor substrate of a first material and the second semiconductor die comprises a second semiconductor substrate of a second material, and the first material and the second material are different.

13. The Doherty amplifier circuit according to claim 2, wherein the first variable bandpass circuit comprises:
a passing circuit c configured to pass the radio frequency signal,
a biasing circuit configured to control a bias of the passing circuit, and
a drawing circuit that draws an electric current from the biasing circuit according to the supply voltage.

14. The Doherty amplifier circuit according to claim 2, wherein the supply voltage is a power supply voltage supplied to a final stage amplifier or a voltage corresponding to the power supply voltage.

15. The Doherty amplifier circuit according to claim 3, wherein the supply voltage is a power supply voltage supplied to a final stage amplifier or a voltage corresponding to the power supply voltage.

16. The Doherty amplifier circuit according to claim 4, wherein the supply voltage is a power supply voltage supplied to a final stage amplifier or a voltage corresponding to the power supply voltage.

17. The Doherty amplifier circuit according to claim 6, wherein the control circuit comprises a second variable bandpass circuit that is electrically connected between the first variable bandpass circuit and the detector, and configured such that a second bandpass for passing the radio frequency signal is variable and the second bandpass increases as a drive level of an amplifier other than the peak amplifier increases.

18. The Doherty amplifier circuit according to claim 9, wherein the control circuit comprises:
a first variable bandpass circuit configured such that a bandpass for passing the radio frequency signal is variable according to a supply voltage, and
a detector configured to detect the radio frequency signal passing through the first variable bandpass characteristic circuit.
